(19) United States
(12) Patent Application Publication
(10) Pub. No.: US 2015/0271946 A1
(43) Pub. Date: Sep. 24, 2015

(54) ELECTRICAL CONNECTORS FOR POWER SUPPLIES

(71) Applicant: HEWLETT PACKARD DEVELOPMENT COMPANY, L.P., Houston, TX (US)

(72) Inventors: Mohamed Amin Bemat, Cypress, TX (US); Daniel Humphrey, Cypress, TX (US)

(21) Appl. No.: 14/440,851

(22) PCT Filed: Nov. 19, 2012
(86) PCT No.: PCT/US12/65915

§ 371 Date: May 5, 2015

(51) Int. Cl. H05K 7/14; H01R 13/518; H01R 13/642

(52) U.S. Cl. CPC H05K 7/1492; H01R 13/642; H01R 13/518

(57) ABSTRACT

Various electrical connectors each include respective signal nodes and power nodes arranged in accordance with a ninety-degree rotational symmetry. Such a connector can be part of a power supply that is receivable within different entity housings in either a horizontal or vertical orientation. The symmetry of such connector presents a common node pattern to a complimentary connector at four, right-angle rotational increments. Power supplies equipped with such a connector are interoperable with various servers or other load entities.

### BACKGROUND

Power supplies are used to provide conditioned electrical energy within a broad range of various systems. Reducing parts count is continually sought after, as is interoperability of system components.

### BRIEF DESCRIPTION OF THE DRAWINGS

The present embodiments will now be described, by way of example, with reference to the accompanying drawings, in which:

FIG. 1 depicts an isometric-like view of an arrangement of elements according to one example of the present teachings;

FIG. 2 depicts isometric-like views of male and female connectors according to another example;

FIG. 3 depicts an isometric-like view of an arrangement of elements according to one example of the present teachings;

FIG. 4 depicts a plan diagrammatic view of a server according to another example;

FIG. 5 depicts a plan of an illustrative electrical connector according to another example of the present teachings;

FIG. 6 depicts a plan of an illustrative electrical connector according to yet another example;

FIG. 7 depicts a plan of an illustrative electrical connector according to still another example;

FIG. 8 depicts isometric-like views of a power supply in respective vertical and horizontal orientations; and

FIG. 9 is a flow diagram of a method according to yet another example of the present teachings.

### DETAILED DESCRIPTION

### Introduction

Various electrical connectors each include respective signal nodes and power nodes arranged in accordance with a ninety-degree rotational symmetry. Such a connector can be part of a power supply that is receivable within different entity housings in either a horizontal or vertical orientation. The symmetry of such connector presents a common node pattern to a complimentary con lector at four, right-angle rotational increments, Power supplies equipped with such a connector are interoperable with various servers or other load entities.

In one example, an electrical connector includes a connector body characterized by a facial area, and a plurality of signal nodes supported within the facial area and arranged as a square array. The square array is centered on the facial area. The electrical connector further includes a plurality of power nodes supported about the signal nodes and within a perimeter of the facial area.

In another example, a power supply includes a housing and electrical circuitry disposed within the housing. The power supply also includes an electrical connector supported by the housing. The electrical connector includes a plurality of signal nodes, and the electrical connector includes a plurality of power nodes arranged about the signal nodes in accordance with a ninety-degree rotational symmetry. The electrical circuitry is to provide conditioned electrical energy by way of the power nodes.

### First Illustrative Arrangement

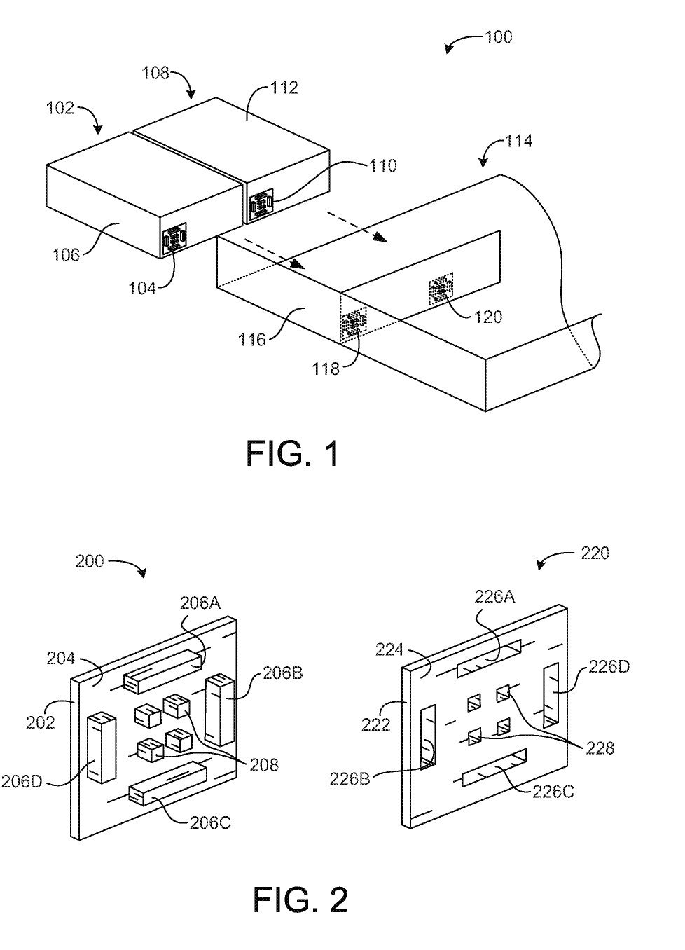

Attention is directed now to FIG. 1, which depicts an arrangement 100 of elements in accordance with an illustrative embodiment of the present teachings. Other arrangements having respectively varying constituencies or configurations can also be used.

The arrangement 100 includes a power supply 102 including an electrical connector 104. The power supply 102 includes electrical circuitry to provide conditioned electrical energy (e.g., regulated voltages) and communicates signals (e.g., data) by way of respective nodes of the electrical connector 104. The power supply 102 is also defined by a housing 106. The housing 106 supports the electrical connector 104 and is configured to be received, at least in part, within a housing or chassis of another entity.

The arrangement 100 also includes a power supply 108 including an electrical connector 110. The power supply 108 includes electrical circuitry to provide conditioned electrical energy and communicates signals by way of the electrical connector 110. The power supply 108 is also defined by a housing 112, which supports the electrical connector 110 and is configured to be received, at least in part, within a housing or chassis of another entity. In one or more examples, the respective power supplies 102 and 108 are identical to each other, In one or more other examples, at least the electrical connectors 104 and 110 are identical to each other.

The arrangement 100 also includes an entity 114. In one non-limiting example, the entity 114 is a defined by a 1U rack-mountable server. Other entities 114 can also be used. The entity 114 includes a chassis (or housing) 116 to receive each of the power supplies 102 and 108 there within in a horizontal orientation.

The entity 114 also includes an electrical connector 118. The electrical connector 118 is disposed and is of complementary form (i.e., gender) so as to disconnectably electrically mate with the electrical connector 104 of the power supply 102 (or the electrical connector 110 of the power supply 108). In one non-limiting example, the electrical connector 104 is of male gender (defined by respective pins) and the electrical connector 118 is of female gender (defined by sockets to receive the respective pins). Other compatible gender combinations can also be used.

The entity 114 further includes an electrical connector 120, disposed and of complementary form so as to disconnectably electrically mate with the electrical connector 110 of the power supply 108 (or the electrical connector 104 of the power supply 102). The entity 114 is therefore configured to receive one or two power supplies 102 and 108 within the chassis 116, and to be electrically coupled thereto by way of respective electrical connectors 104, 110, 118 and 120, The entity 114 receives conditioned electrical energy from, and bidirectionally communicates signals with, the respective power supplies 102 and 108.

### Illustrative Male and Female Connectors

Reference is now made to FIG. 2, which depicts an isometric-like view of respective electrical connectors (connectors) 200 and 220 according to the present teachings. The connectors 200 and 220 are illustrative and non-limiting with respect to the present teachings. Other configurations, materials, element counts and form factors in accordance there with are also contemplated.

The connector 200 includes an electrically non-conductive material defining a body 202 having facial area (face) 204 characterized by a square outer perimeter (shape or form-factor). The material of the body 202 can be defined by thermoplastic, nylon, or another suitable material. The connector 200 also includes four respective, electrically conductive power nodes 206A, 206B, 206C and 206D.

Each of the power nodes 206A-206D has a generally elongated bar-like form, extending outward from the face 204, thus defining a male gender for the connector 200. Other shapes or form-factors can also be used. Each of the power nodes 206A-206D is (or can be) coupled to corresponding circuitry or other resources so as to provide (or. receive) electrical power.

The connector 200 also includes four respective, electrically conductive signal nodes 208. Each of the signal nodes 208 has a square cross-sectional form extending outward from the face 204, consistent with the male gender of the connector 200. Other shapes or form-factors can also be used. The signal nodes 208 are arranged as a square array that is centered on the face 204 of the connector 200. That is, the signal nodes 208 are separated by equal spacing (or pitch) in both orthogonal directions on the plane of the face 204.

The power nodes 206A-206D and the signal nodes 208 are respectively arranged according to a ninety-degree rotational symmetry. That is, the connector 200 can be rotated ninety degrees from its depicted orientation and still electrically and mechanically mate with a corresponding (complimentary) connector. Such ninety-degree rotational symmetry allows a power supply using the connector 200 to operate in either a vertical or horizontal orientation with respect to a rack-mounted server or other load entity.

In turn, the connector 220 includes an electrically non-conductive body 222 defining a facial area (face) 224 having a square outer perimeter. The material of the body 222 can be defined by thermoplastic, nylon, or another suitable material. The connector 220 also includes four respective power nodes 226A, 226B, 226C and 226D.

Each of the power nodes 226A-226D is defined by an electrically conductive socket extending inward from the face 224, thus defining a female gender for the connector 220. The connector 220 is gender and form-factor compatible with (Le., complimentary to) the connector 200. Each of the power nodes 226A-226D is (or can be) coupled to corresponding circuitry so as to provide (or receive) electrical power.

The connector 220 also includes four respective, electrically conductive signal nodes 228. Each of the signal nodes 228 is defined by an electrically conductive socket extending inward from the face 224, consistent with the female gender of the connector 220. Other shapes or form-factors can also be used, The signal nodes 228 are arranged as a square array that is centered on the face 224 of the connector 220.

The power nodes 226A-226D and the signal nodes 228 are respectively arranged according to a ninety-degree rotational symmetry. That is, the connector 220 can mate with a connector 200 that is rotated in ninety degrees increments from its depicted orientation. Such rotational symmetry allows a rack-mounted server or other load entity using the connector 220 to receive a power supply in either a vertical or horizontal orientation.

### Second Illustrative Arrangement

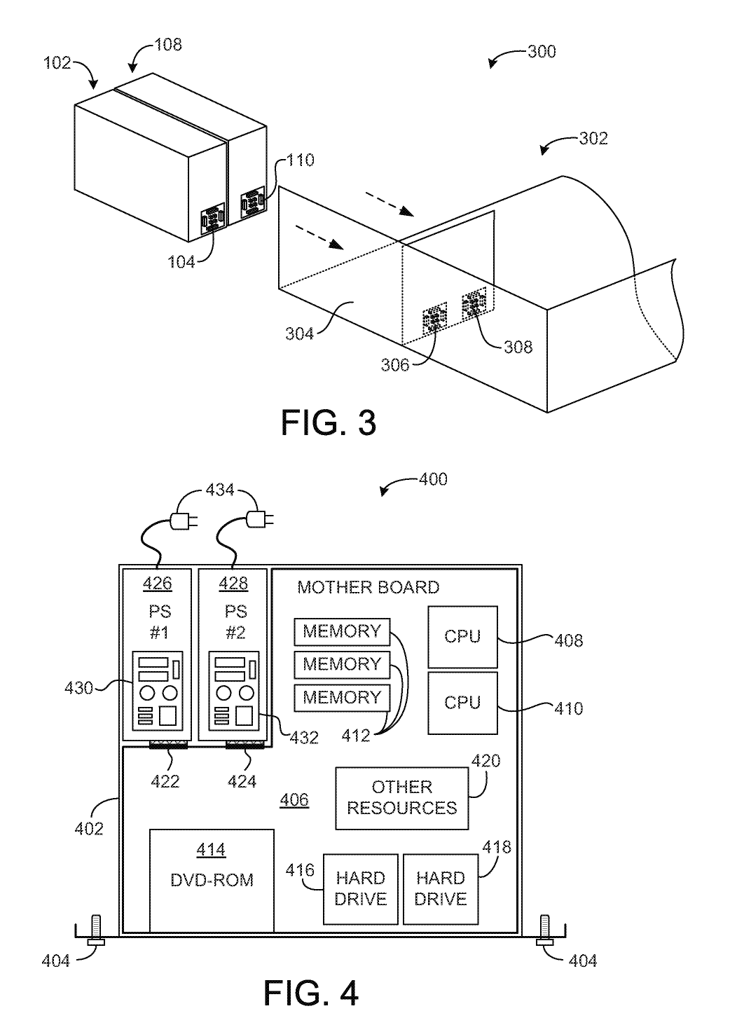

Attention is now directed to FIG. 3, which depicts an arrangement 300 of elements in accordance with an illustrative embodiment of the present teachings. Other arrangements having respectively varying constituencies or configurations can also be used.

The arrangement 300 includes the power supply 102 and the power supply 108 as described above. The arrangement 300 also includes an entity 302. In one non-limiting example, the entity 302 is a defined by a 2U rack-mountable server. Other entities 302 can also be used. The entity 302 includes a chassis 304 to receive each of the power supplies 102 and 108 in a vertical orientation there within.

The entity 302 also includes an electrical connector 306 that is disposed and of complementary gender so as to disconnectably electrically mate with the electrical connector 104 of the power supply 102 (or the electrical connector 110 of the power supply 108). The entity also includes an electrical connector 308 that is disposed and of complementary gender so as to disconnectably electrically mate with the electrical connector 110 of the power supply 108 (or the electrical connector 104 of the power supply 102).

The entity 302 is therefore configured to receive one or two power supplies 102 and 108 within the chassis 304, and to be electrically coupled thereto by way of respective electrical connectors 104, 110, 306 and 308. The entity 302 receives conditioned electrical energy from, and bidirectionaliy communicates signals with, the respective power supplies 102 and 108.

### Illustrative Server

Reference is now made to FIG. 4, which depicts a plan diagram view of a server 400 in accordance with the present teachings. The server 400 is illustrative and non-limiting, and other servers, systems, devices and configurations can be used accordingly.

The server 400 includes a chassis (or housing) 402 that includes a pair of mounting fasteners 404. The housing 402 is configured to support various elements there within and to support the server 400 within a rack mounting system. The housing 402 can optionally include other features as well, which are not germane to the present teachings. The server 400 includes a motherboard (or circuit board) 406 supported within the housing 402. The motherboard 406 is configured to support various elements described hereinafter and to couple those elements in electrical communication with each other by way of respective circuit pathways.

The server 400 also includes respective central processing units (CPUs) or processors 408 and 410. Each CPU 408 and 410 performs various functions in accordance with a machine-readable program code. Thus, the functions and operations of the server 400 are defined largely by the actions of the CPUs 408 and 410. The server 400 also includes respective memories 412. Each memory 412 is coupled in bidirectional communication with the CPUs 408 and 410, and can be defined by any suitable solid-state storage. Digital information can be stored within and retrieved from the respective memories 412.

The server 400 further includes a digital video disk read-only memory (DVD-ROM) drive 414. The DVD-ROM 414 reads digital information encoded upon corresponding optical storage media and communicates that information to one or both of the CPUs 408 and 410. Program code, data files or other information can be retrieved from the DVD-ROM 414. The server 400 also includes respective hard drives 416 and 418. Each of the hard drives 416 and 418 is configured to store digital data on, and retrieve such information from, a magnetic storage media therein. Each of the hard drives 416 and 418 is coupled in bidirectional communication with the CPUs 408 and 410.

The server includes other resources 420. Such other resources 420 can be variously defined, and non-limiting examples include cooling fans, network communication circuitry, wireless resources, a user interface, a status display or annunciator panel, and so on. Other resources 420 can also be used, and coupled in cooperative relationship with other elements of the server 400 accordingly.

The server 400 also includes an electrical connector 422 and an electrical connector 424, each in accordance with the present teachings. The respective electrical connectors 422 and 424 are supported by the motherboard 406 and are electrically coupled to respective circuit pathways. Electrical operating power can be received and electronic signals can be communicated by way of respective nodes of the electrical connectors 422 and 424, In one example, each of the electrical connectors 422 and 424 is equivalent to the electrical connector 220 described above. Other suitable connectors according to the present teachings can also be used.

The server 400 further includes respective power supplies 426 and 428. The power supplies 426 and 428 are received within the housing 402 in a vertical orientation, and are electrically mated to the electrical connectors 422 and 424, respectively. The power supplies 426 and 428 provide conditioned electrical energy to, and communicate data or other electronic signals with, the server 400 by way of respective electrical (or electronic) circuits 430 and 432.

In one non-limiting example, each of the power supplies 426 and 428 includes an electrical connector equivalent to connector 200 described above. Other suitable connectors according to the present teachings can also be used. The electrical circuits 430 and 432 are configured to be coupled to a source of (e.g., le-level utility) electrical energy by way of a respective cord-and-plug set 434.

### First Illustrative Connector

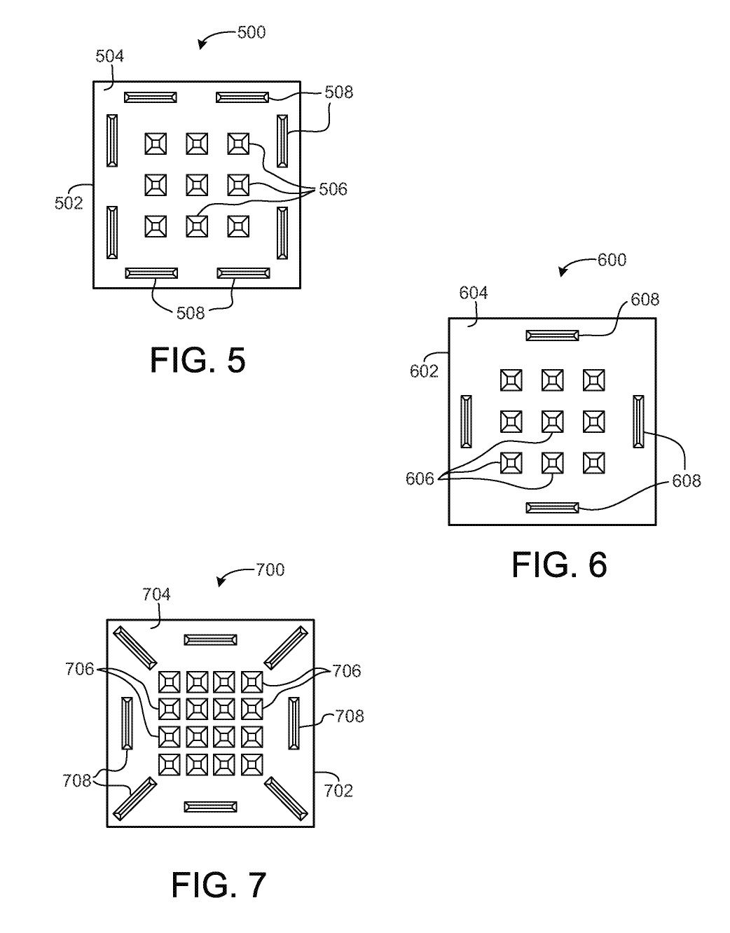

Attention is turned now to FIG. 5, which depicts a plan of an electrical connector (connector) 500 in accordance with the present teachings. The connector 500 includes particular elements and their configuration. Other connectors including other elements, other element counts or configurations can also be used.

The connector 500 includes a connector body (body) 502. The body 502 is formed from (or includes) an electrically non-conductive material such as thermoplastic or the like. The body 502 is characterized by a square perimeter and a planar facial area 504.

The connector 500 also includes nine respective, electrically-conductive signal pins (nodes) 506 arranged as a square array. Each of the signal pins 506 extends outward away from the facial area 504, thus defining a male gender for the connector 500. Each signal pin 506 is defined by a square cross-sectional form and a tapered tip portion so as to guide during sliding reception of the signal pin 506 within a corresponding socket.

The connector 500 also includes eight respective, electrically-conductive power pins (nodes) 508 arranged uniformly about the signal pins 506. Each of the power pins 508 extends outward away from the facial area 504 in accordance with the male gender of the connector 500. Each power pin 508 is defined by an elongated rectangular cross-sectional form. Each of the power pins 508 tapers at an outer end portion as to aid that pin during reception within a corresponding socket.

The signal pins 506 and the power pins 508 are respectively and collectively arranged in accordance with a ninety-degree rotational symmetry. That is, the connector 500 can be rotated clockwise (or counter-clockwise) in ninety-degree (right angle) increments while presenting the same pin (node) arrangement pattern to a corresponding female connector. For example, the connector 500 can be used in either a first orientation, or a second orientation rotated ninety-degrees relative to the first, in accordance with a horizontal or vertical mating of a power supply with a connector of a load entity.

### Second Illustrative Connector

Attention is now directed to FIG. 6, which depicts a plan of an electrical connector (connector) 600 in accordance with the present teachings. The connector 600 includes particular elements and their configuration. Other connectors including other elements, other element counts or configurations can also be used.

The connector 600 includes a connector body (body) 602. The body 602 is formed from an electrically non-conductive material, and is characterized by a square perimeter and a planar facial area 604.

The connector 600 also includes nine respective, electrically-conductive signal pins (nodes) 606 arranged as a square array. Each of the signal pins 606 extends outward away from the facial area 604, thus defining a male gender. Each signal pin 606 is defined by a square cross-sectional form and a tapered tip portion.

The connector 600 also includes four respective, electrically-conductive power pins (nodes) 608 arranged uniformly about the signal pins 606. Each of the power pins 608 extends outward away from the facial area 604, and is defined by a rectangular cross-sectional form. Each of the power pins 608 also tapers at an outer end portion.

The signal pins 606 and the power pins 608 are respectively and collectively arranged in accordance with a ninety-degree rotational symmetry. The connector 600 can therefore be rotated clockwise (or counter-clockwise) in ninety-degree increments while presenting the same pattern to a corresponding female connector.

### Third Illustrative Connector

Attention is now directed to FIG. 7, which depicts a plan of an electrical connector (connector) 700 in accordance with the present teachings. The connector 700 includes particular elements and their configuration. Other connectors including other elements, other element counts or configurations can also be used.

The connector 700 includes a connector body (body) 702. The body 702 is formed from an electrically non-conductive material, and is defined by a square perimeter and a planar facial area 704. The connector 700 also includes sixteen respective, electrically-conductive signal pins (nodes) 706 arranged as a square array. Each of the signal pins 706 extends outward away from the facial area 704, thus defining a male gender. Each signal pin 706 is defined by a square cross-sectional form and a tapered tip portion.

The connector 700 also includes eight respective, electrically-conductive power pins (nodes) 708 arranged uniformly about the signal pins 706. Each of the power pins 708 extends outward away from the facial area 704, and is defined by a rectangular cross-sectional form. Each of the power pins 708 tapers at an outer end portion.

The signal pins 706 and the power pins 708 are respectively and collectively arranged in accordance with a ninety-degree rotational symmetry. The connector 700 can therefore be rotated in ninety-degree increments while presenting the same pattern to a corresponding female connector.

The illustrative and non-limiting connectors 500, 600 and 700 described above are just a few examples consistent with the present teachings. Generally, and not exclusively, electrical connectors are contemplated each including a plurality of signal nodes arranged in an array or other symmetrical pattern and centered on a connector body face. Power nodes are arranged on the face around the signal nodes such that an overall ninety-degree rotational symmetry is defined. Such electrical connectors can be rotated in right-angle increments while still presenting a common pin or socket (node) pattern to a complimentary electrical connector.

### Illustrative Power Supply Orientations

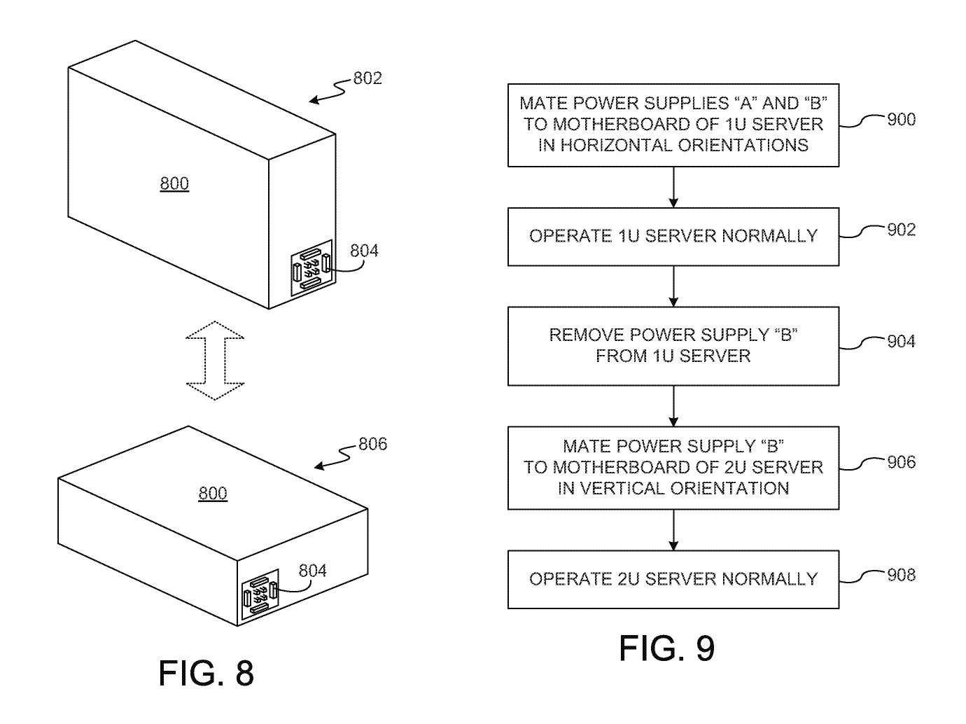

Attention is turned now to FIG. 8, which depicts a power supply 800 in two respective orientations. The power supply 800 and orientations thereof are illustrative and non-limiting, and other power supplies, positional orientations or characteristics are also contemplated.

The power supply 800 is depicted in a vertical orientation 802, defined by an upright positioning and having an electrical connector 804 disposed in a lower-right end location. The electrical connector 804 can be defined by any suitable electrical connector in accordance with the present teachings, characterized by a ninety-degree rotational symmetry as described above.

The power supply 800 is also depicted in a horizontal orientation 806, defined by a generally laid-over positioning and having the electrical connector 804 disposed in a lower-left end location. The power supply 800 will operate normally in either the vertical orientation 802 or the horizontal orientation 806, with the connector 804 presenting the same node pattern to a complimentary connector.

### Illustrative Method

Reference is made now to FIG. 9, which depicts a flow diagram of a method according to the present teachings. The method of FIG. 9 includes particular steps performed in a particular order of execution. However, other methods including other steps, omitting one or more of the depicted steps, or proceeding in other orders of execution can also be defined and used. Thus, the method of FIG. 9 is illustrative and non-limiting with respect to the present teachings. Reference is also made to FIGS. 1, 3 and 4 in the interest of illustrating the method of FIG. 9.

At 900, power power supplies “A” and “B” are mated to a motherboard of a 1U server in horizontal orientations. For purposes of a present example, the power supply 102 (“A”) and the power supply 108 (“B”) are mated to electrical connectors 118 and 120, respectively, within the entity 114. It is understood that the entity 114 is defined by a 1U server having a motherboard (e.g., 406) electrically coupled to the connectors 118 and 120.

At 902, the 1U server is operated normally. In the present example, the 1U server 114 operates to perform various functions in accordance with a machine-readable program code. The entity 114 receives operating power from the power supplies 102 (“A”) and 108 (“B”), and communicates respective status, command or other signals therewith.

At 904, the power supply “B” is removed from the 1U server. For purposes of the present example, the power supply 108 (“B”) is removed from the 1U server 114. The 1U server 114 continues to operate, possibly at reduced intensity, by way of the remaining power supply 102 (“A”).

At 906, power supply “B” is mated to a motherboard of a 2U server in a vertical orientation. For purposes of a present example, the power supply 108 (“B”) is mated to an electrical connector 308 within the entity 302. It is understood that the entity 302 is defined by a 2U server having a motherboard (e.g., 406) electrically coupled to the connectors 306 and 308.

At 908, the 2U server is operated normally. In the present example, the 2U server 302 operates to perform various functions in accordance with a machine-readable program code. The 2U server 302 receives operating power from the power supplies 108 CB″) and communicates respective status, command or other signals therewith.

In general, the present teachings contemplate devices, system and methods using electrical connectors defined by a ninety-degree rotational symmetry. Such a connector includes signal nodes (pins or sockets) arranged in a regular, symmetrical pattern (e.g., square array) and centered on a face of the connector. Power nodes are arranged around the signal nodes in accordance with the rotational symmetry. A power supply equipped with such a connector can be mated to various servers, computers or other devices in at least two respective orientations being at right angles to each other.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An electrical connector, comprising:
a connector body characterized by a facial area;
a plurality of signal nodes supported within the facial area and arranged as a square array, the square array centered on the facial area; and
a plurality of power nodes supported about the signal nodes and within a perimeter of the facial area.

2. The electrical connector according to claim 1, the power nodes and the signal nodes arranged in accordance with a ninety-degree rotational symmetry.

3. The electrical connector according to claim 1, the power nodes arranged symmetrically with respect to the square array of signal nodes,

4. The electrical connector according to claim 1, each of the power nodes being of greater cross-sectional area than each of the signal nodes.

5. The electrical connector according to claim 1, the connector body defined by a perimeter shape in accordance with a ninety-degree rotational symmetry.

6. The electrical connector according to claim 1, the connector body formed from an electrically nonconductive material, each of the signal nodes and each of the power nodes formed from an electrically conductive material.

7. The electrical connector according to claim 1, each of the signal nodes defined by either a male or a female gender.

8. The electrical connector according to claim 1, each of the power nodes defined by either a male or a female gender,

9. A power supply, comprising:
a housing;
electrical circuitry disposed within the housing; and
an electrical connector supported by the housing, the electrical connector including a plurality of signal nodes, the electrical connector including a plurality of power nodes arranged about the signal nodes in accordance with a ninety-degree rotational symmetry, the electrical circuitry to provide conditioned electrical energy by way of the power nodes.

10. The power supply according to claim 9, the electrical circuitry to communicate electronic signals with another entity by way of the signal nodes.

11. The power supply according to claim 9, the electrical connector to be disconnectably mated with a corresponding connector of another entity.

12. The power supply according to claim 9, the housing to be received within a chassis of at least one type of rack-mountable computer server.

13. The power supply according to claim 9, the electrical connector to electrically mate with one or more other entities when the power supply is in a horizontal orientation, the electrical connector to electrically mate with one or more other entities when the power supply is in a vertical orientation.

14. The power supply according to claim 9, the signal nodes arranged as a square array and centered on the electrical connector.

15. The power supply according to claim 9, the electrical connector defined by a perimeter shape in accordance with the ninety-degree rotational symmetry.
